(19) United States
(12) Patent Application Publication
(10) Pub. No.: US 2005/0259385 A1
(43) Pub. Date: Nov. 24, 2005

(54) Comfort enhancing surface for electronic device

(76) Inventors: Mark Solomon, Cypress, TX (US); Kevin Luke Massaro, Houston, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/853,457

(22) Filed: May 24, 2004

(51) Int. Cl. H05K 5/00

(52) U.S. Cl. 361/679

(57) ABSTRACT

An electronic device comprises a face with a multi-level surface characteristic that reduces the surface area in contact with a user of the device, thereby attenuating the heat transfer between the device and the user, and therefore also attenuating the touch temperature of the device surface.

### FIELD OF THE INVENTION

The present invention relates generally to electronic devices, and more specifically to the thermal characteristics of electronic devices.

### BACKGROUND OF THE INVENTION

As portable computers have become more capable, their power consumption has increased as well. Considerable power is required to enable the computation and storage capabilities of a modern computer. Much of the energy consumed by a computer becomes waste heat, which escapes from the computer housing, at least some of it by conduction through the materials of the computer housing. Increasingly, the outer surfaces of modern computers approach or reach temperatures that are uncomfortable to the computer user's touch. This problem is especially troublesome in “laptop” or “notebook” portable computers, which may be operated on a user's lap.

Some waste heat may be expelled from a computer enclosure using fan-driven convection. However, a powerful fan may create acoustical noise that is unwanted in an environment, such as a business meeting, where a portable computer is likely to be used. Also, the fan itself consumes additional power. Portable computers are often operated on limited energy supplies, such as one or more batteries, and it is highly desirable to design the computer to operate for as long a period as possible on its limited resources.

Other kinds of electronic devices suffer similar problems.

### SUMMARY OF THE INVENTION

An electronic device comprises a face with a multi-level surface characteristic that reduces the surface area in contact with a user of the device, thereby attenuating the heat transfer between the device and the user, and thereby also attenuating the touch temperature of the device surface.

### BRIEF DESCRIPTION OF THE DRAWINGS

FIGS. 1A and 1B show simplified perspective views of a typical prior art laptop portable computer.

FIG. 2 depicts a bottom perspective view of a laptop portable computer in accordance with a first example embodiment of the invention.

FIG. 3 shows an enlarged view of a portion of FIG. 2.

FIG. 4 shows a cross section view of example ribs shown in FIGS. 2 and 3.

FIG. 5 shows a laptop portable computer in accordance with a second example embodiment of the invention.

FIG. 6 shows an enlarged view of a portion of FIG. 5.

FIG. 7 shows a portion of a laptop portable computer in accordance with a third example embodiment of the invention.

### DETAILED DESCRIPTION

The apparent surface temperature, or “touch temperature” of an electronic device depends several factors. Of course, the actual temperature of the outer surface of the electronic device is a factor in how the temperature of the surface is perceived by a person touching it. But two surfaces of equal actual temperature may not necessarily appear, to the sense of touch, to be the same temperature because other surface characteristics can affect the perception of temperature.

In addition to the actual temperature of the surface, other factors that can affect the touch temperature include the thermal conductivity of the material the surface is made of, the surface finish, the specific heat of the material, and the duration of the touch. In general, material or surface characteristics that tend to inhibit heat transfer between the surface and human skin in contact with the surface will also tend to attenuate perceived extremes in the touch temperature of the surface. For example, a steel filing cabinet at room temperature will feel much cooler than a plastic surface nearby, even though both have long since equilibrated to the temperature of the room. Steel has a much higher thermal conductivity than plastic, so heat transfers much more rapidly from human skin to steel at room temperature than to plastic at room temperature. The human sensory system interprets this more rapid heat loss as an indication that the steel surface is colder than the plastic surface.

Similarly, the touch temperatures of surfaces that are at higher temperatures than human skin are affected by similar material characteristics. For example, a cook may test the doneness of a cake by reaching into a hot oven and briefly touching the exposed cake surface with minimal discomfort. However, touching an aluminum pan that the cake is baking in may result in instant and extreme discomfort, even though the cake and the pan are at nearly the same actual temperature. Because aluminum is an especially good conductor of heat, temperature differences between aluminum surfaces and human skin in contact with the surfaces appear amplified by the rapid transfer of heat to or from the skin.

A “laptop” portable computer serves as an example of an electronic device in which the invention may be advantageously embodied.

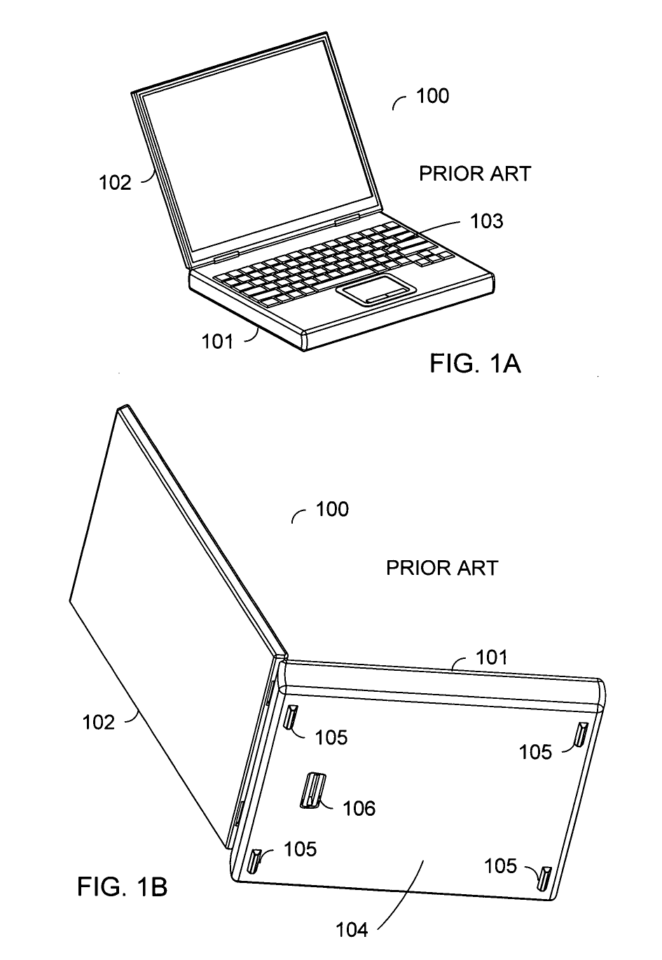

FIGS. 1A and 1B show simplified perspective views of a typical prior art laptop portable computer 100. Laptop portable computer 100 comprises a base portion 101 and a display portion 102. Base portion 101 may further comprise a microprocessor, memory, mass storage, batteries, and a keyboard 103. Display portion 102 comprises a display on which computer 100 displays its user interface.

Base portion 101 also comprises a back face 104. Back face 104 is substantially smooth, except for small items such as feet 105, docking connector 106, and other incidental items (not shown) such as access door latches, recesses for fastener heads, and the like. Other than such small protuberances and indentations, the majority of back face 104 is an unbroken plane of only nominal roughness, as may be formed by a light texture used in a plastic mold. A typical surface roughness for back face 104 may be about 15 to 30 micrometers.

A laptop portable computer such as computer 100 may often be operated while resting on the lap of a computer user. In such a position, back face 104 is in close proximity to the user's skin, separated from it by at most the user's clothing. Due to heat generated inside computer base unit 101 and escaping through back face 104, back face 104 may reach an actual temperature that makes it uncomfortably hot when the computer is used for an extended period of time. The generally smooth nature of back face 104 facilitates heat transfer to the user's body, by maximizing the surface area in contact with the user.

Heat transfer across an interface may be characterized by the simplified equation
Q=A×C×ΔT
where:
Q is the heat flow, measured in watts,
A is the surface area of the interface, measured in square meters,
C is the composite thermal conductivity of the interface materials, measured in watts per square meter per degree Celsius, and
ΔT is the temperature differential across the interface, measured in degrees Celsius.

Of course, heat flows in the direction from the higher-temperature side of the interface to the lower-temperature side.

The touch temperature of a surface can be attenuated by reducing the heat transfer between the surface and the touching skin. An electronic device in accordance with an example embodiment of the invention comprises a surface characteristic that attenuates the heat transfer between the device and a user of the device, and therefore also attenuates the touch temperature of the device surface. Specifically, the surface characteristic reduces the surface area available for transferring heat, thereby reducing the heat transfer.

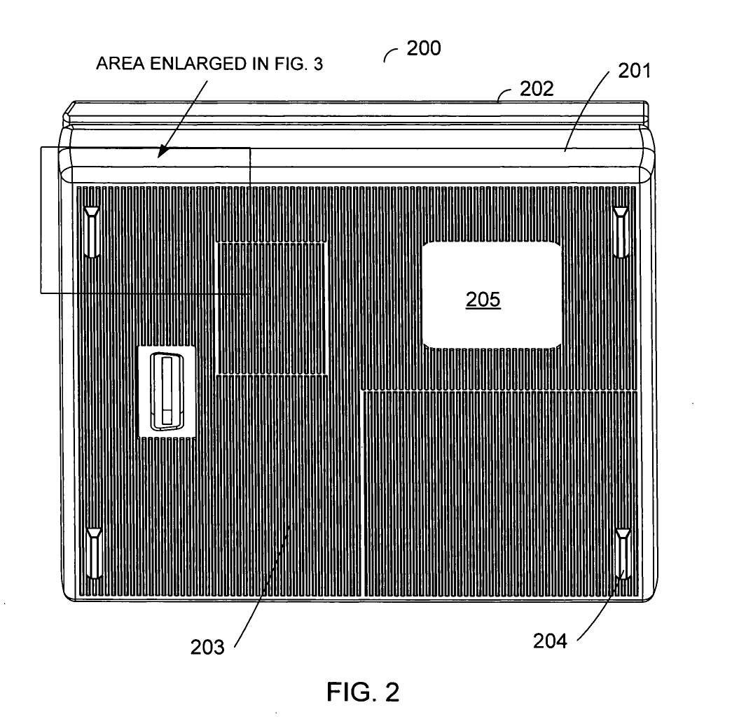

FIG. 2 depicts a bottom perspective view of a laptop portable computer 200 in accordance with a first example embodiment of the invention. Laptop portable computer 200 comprises a base portion 201, and a display portion 202. Display portion 202 is shown in its closed position. Laptop portable computer 200 is capable of portable operation. That is, it can be operated while disconnected from any power source external to itself, using power supplied by one or more internal batteries. While laptop portable computer is capable of portable operation, it may also be capable of drawing power from an external source, such as a standard wall socket. Operating computer 200 using power from the external source may allow it to be used for a longer period of time than is possible during portable operation, and may provide power for recharging the computer's internal batteries.

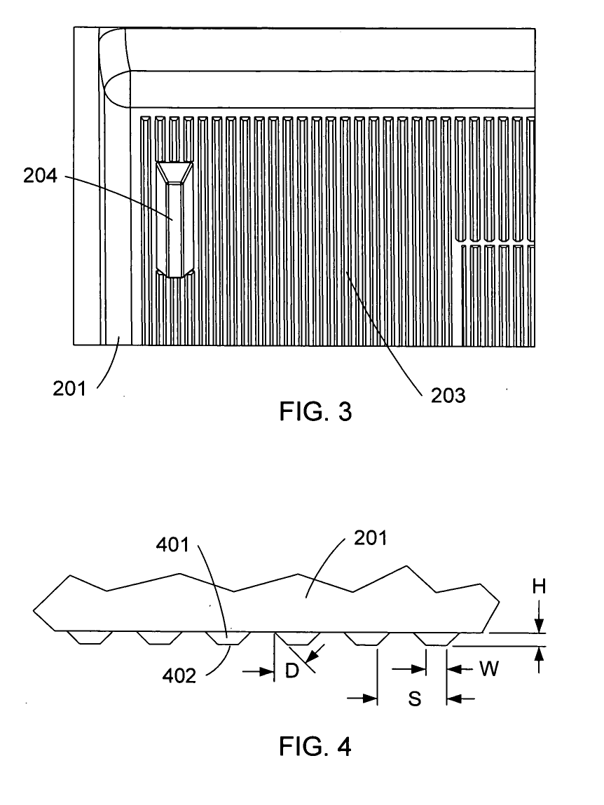

A bottom face 203 of base portion 201 is substantially covered by a set of raised ribs of trapezoidal cross section formed onto bottom face 203. The set of ribs may be interrupted by relatively small protrusions such as feet 204, by an area 205 for affixing a label, or by other features, but the bulk of bottom face 203 is covered by the ribs. FIG. 3 shows an enlarged perspective view of a portion of the set of ribs, for clearer viewing.

FIG. 4 shows a magnified end view of the ribs of FIGS. 2 and 3. In a preferred embodiment, the bottom face 203 of computer 200 may be made of a molded engineered plastic such as polycarbonate, acrylonitrile butadiene styrene (ABS), or another similar material, or a blend of such materials. The example ribs of FIG. 4 have a nominal height (H) of 0.5 millimeters, a nominal top width (W) of 0.8 millimeters, and nominal a rib-to-rib spacing distance (S) of 2.7 millimeters. The side walls of the ribs are drafted at a nominal draft angle (D) of 45 degrees. Other dimensions may be used as well. The spaces between the ribs do not form openings in bottom face 203, although the ribs may be incorporated into a grille for a fan that forces air into or out of computer 200.

The set of ribs thus forms a multi-level surface characteristic on face 203. The tops of the ribs form one level, while the areas between the ribs form a second level. The top surface of a rib is the surface most displaced from the main portion of base portion 201. For example, with reference to FIG. 4, surface 402 is the top surface of particular rib 401. The drafted portions of the ribs form other levels. When laptop portable computer 200 is held on a user's lap, most of the contact of the computer with the user occurs at the top surfaces of the ribs.

For the purposes of this disclosure, a device face or surface is in contact with a user when the surface touches the user's skin, or when the face or surface and the user's skin are separated by the user's clothing.

If the rib dimensions are those given above, then the surface area in contact with the user is approximately 30 percent of surface area that would contact the user if bottom face 203 were smooth. Since the surface area available for heat transfer is reduced, the heat transfer across the interface from computer 200 to the user is attenuated, and the touch temperature of bottom face 203 is attenuated. In other words, the computer does not feel as warm as it would with a smoother bottom face. The computer can therefore be used for a longer time before discomfort occurs.

Of course, even if designed in accordance with an example embodiment of the invention, the computer 200 should also be designed so that the actual temperature of the outer surface does not exceed safe operating limits. Even though heat transfer from the computer to the user is slowed, the user's skin may eventually reach nearly the temperature of computer bottom face 203, depending upon the temperatures involved, the clothing the user may be wearing, and the capacity of the user's body to absorb and dissipate the heat entering it through natural mechanisms.

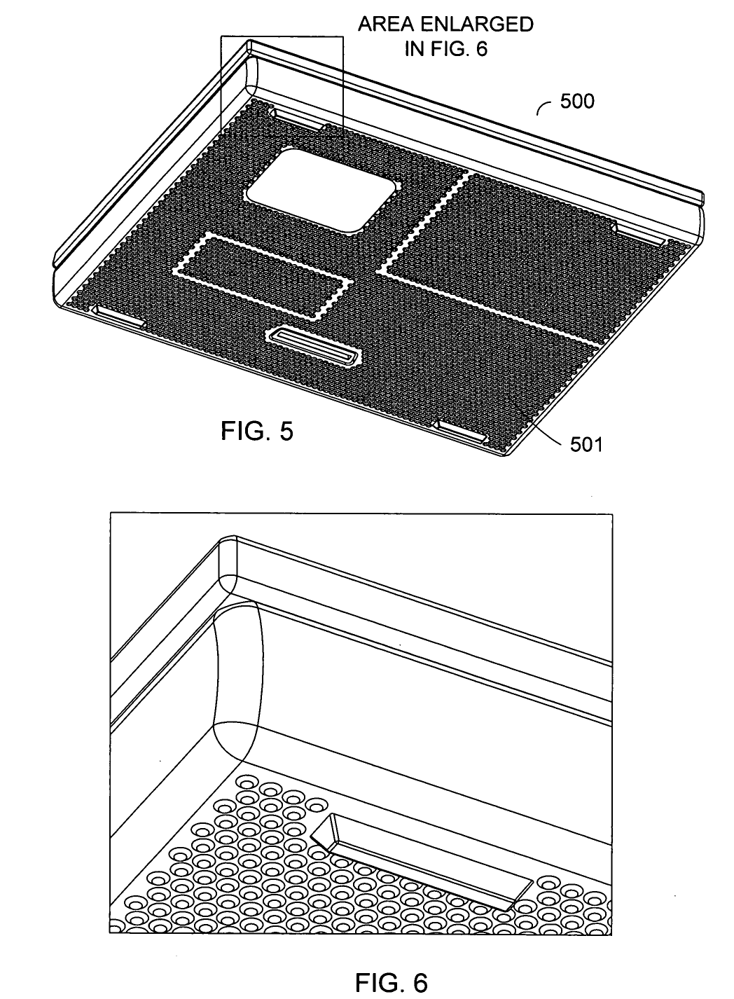

FIG. 5 shows a laptop portable computer 500 in accordance with a second example embodiment of the invention. In this second example embodiment, bottom face 501 of computer 500 is substantially covered with isolated raised protrusions, rather than the ribs used in example computer 200. FIG. 6 shows a magnified view of a portion of FIG. 5, for clearer viewing of the raised protrusions. Each raised protrusion is a frustum of a cone. The example protrusions of FIGS. 5 and 6 have a nominal base diameter of 3.4 millimeters, a nominal top diameter of 2.0 millimeters, and a nominal height of 0.7 millimeters. The protrusions are arranged so that they are spaced apart by a nominal distance of 4.0 millimeters. Using these example dimensions, the surface area in contact with the user, when computer 500 is placed on a user's lap, is about 23 percent of the surface area that would contact the user if bottom face 501 were smooth.

Other dimensions may be used as long as the surface characteristic is such that the device, when placed on a user's lap, is substantially supported by the raised portions of the surface features, thereby reducing the surface area in contact with the user. Other feature shapes may also be used. For example, protrusions similar to those of FIGS. 5 and 6 could be frusta of pyramids with any number of sides, or of other geometric shapes. Alternatively, crossed ribs forming a lattice on the face may be used. The spaces between the protrusions do not form openings in the bottom face of the electronic device, although they may be incorporated into a grille for a fan that forces air into or out of the electronic device.

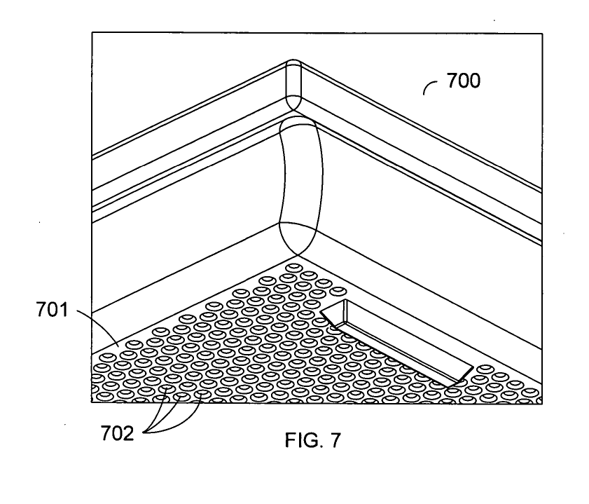

In yet another example embodiment, the reduction in surface area in contact with the user may be accomplished by providing recesses in the product face that is in contact with the user, rather than protrusions on the face. FIG. 7 shows a portion of a laptop portable computer 700 in accordance with this example embodiment of the invention. Laptop portable computer 700 has a bottom face 701. Bottom face 701 is substantially covered with indentations 702 that serve to reduce the surface area in contact with a user when computer 701 is used on the user's lap. In the example of FIG. 7, each indentation 702 has the shape of a frustum of a cone, and has a nominal outer diameter of 3.4 millimeters, a nominal depth of 0.7 millimeters, and a nominal floor diameter of 2.0 millimeters. Other indentation shapes and dimensions could be used. For example, each indentation could have the shape of a frustum of a pyramid of any number of sides, or the indentations could be grooves. Other shapes are possible as well. The indentations do not form openings in the bottom face of the electronic device, although they may be incorporated into a grille for a fan that forces air into or out of the electronic device.

The invention may similarly be embodied in electronic devices other than a laptop portable computer, for example, a portable viewer for digital versatile discs (DVDs). A portable DVD viewer is typically a device comprising a base portion and a screen portion, and that enables a user to view, at any convenient location, the content stored on a DVD. A common use is to view movies or other video entertainment. A portable DVD viewer may be placed on a user's lap while in use.

1. An electronic device, comprising an outer face that is configured to be in contact with a user during operation of the electronic device, and wherein the outer face comprises a multi-level surface characteristic that reduces the surface area in contact with the user, and thereby attenuates the touch temperature of the surface, and wherein the electronic device is capable of portable operation.

2. The electronic device of claim 1, wherein the multi-level surface characteristic is formed by raised features on the surface of the outer face.

3. The electronic device of claim 2, wherein the raised features are ribs.

4. The electronic device of claim 3, wherein the ribs are of trapezoidal cross section.

5. The electronic device of claim 4, wherein the ribs have a top width of about 0.7 millimeters, a height of about 0.5 millimeters, and a rib-to-rib spacing of about 2.7 millimeters.

6. The electronic device of claim 2, wherein the raised features are frusta of cones.

7. The electronic device of claim 2, wherein the raised features are frusta of pyramids.

8. The electronic device of claim 2, wherein the raised features comprise a lattice of crossed ribs.

9. The electronic device of claim 1, wherein the multi-level surface characteristic is formed by indentations in the surface of the outer face.

10. The electronic device of claim 9, wherein the indentations are grooves.

11. The electronic device of claim 9, wherein the indentations have the shape of frusta of cones.

12. The electronic device of claim 9, wherein the indentations have the shape of frusta of pyramids.

13. The electronic device of claim 1, wherein the electronic device is a laptop portable computer.

14. The electronic device of claim 1, wherein the electronic device is a viewer for Digital Versatile Discs.

15. The electronic device of claim 1, wherein the multi-level surface characteristic substantially covers the outer face.

16. The electronic device of claim 1, wherein the multi-level surface characteristic covers at least 80 percent of the outer face.

17. The electronic device of claim 1, wherein the outer face is configured to be in contact with the user's lap during operation of the electronic device.
